(19) United States
(12) Patent Application Publication
(10) Pub. No.: US 2026/0044638 A1
(43) Pub. Date: Feb. 12, 2026

(54) DESIGN SUPPORT APPARATUS AND DESIGN SUPPORT SYSTEM

(71) Applicant: JGC CORPORATION, Kanagawa (JP)

(72) Inventors: Hiroyuki KOITO, Kanagawa (JP); Toshikazu MIYASHITA, Kanagawa (JP); Yoshinori YAMADA, Kanagawa (JP)

(73) Assignee: JGC CORPORATION, Kanagawa (JP)

(21) Appl. No.: 18/995,845

(22) PCT Filed: Feb. 16, 2024
(86) PCT No.: PCT/JP2024/005565

§ 371 Date: Jan. 17, 2025

(30) Foreign Application Priority Data
Mar. 2, 2023 (WO) PCT/JP2023/007875

(51) Int. Cl. G06F 30/13

(52) U.S. Cl. CPC G06F 30/13

(57) ABSTRACT

A design support apparatus is provided and includes: a storage unit for storing a graph structure data in which a component to be provided in a plant being designed are defined as a node, and a connection relationship between two components is defined as an edge; an acquiring unit for acquiring the graph structure data from the storage unit in response to an acquisition request from a terminal apparatus that performs each of multiple design steps; an output unit for outputting the graph structure data to the terminal apparatus; and an updating unit for updating the graph structure data stored in the storage unit based on output data of a design step performed by the terminal apparatus using the graph structure data. The graph structure data is shared among multiple design steps, and becomes more detailed from an upstream step toward a downstream step of the plant design.

### TECHNICAL FIELD

This disclosure relates to a design support apparatus and a design support system.

### BACKGROUND ART

In order to increase the efficiency of plant design, a design support system which supports plant design is known. For example, in Patent Literature 1, there is described a support system which creates a 3D model with attributes in which attribute information on a piping and instrumentation diagram is included in the 3D model by comparing connection information extracted from a 3D model with no attributes and connection information extracted from the piping and instrumentation diagram.

### CITATION LIST

### Patent Literature

[Patent Literature 1] JP 2021-5199 A

### SUMMARY OF INVENTION

### Technical Problem

In the support system as described in Patent Literature 1, although the inclusion of attribute information is automated, each diagram is created separately in a piping and instrumentation diagram creation step and a 3D model creation step. Thus, in related-art plant design, data is prepared and diagrams are created individually for each design step, and this becomes a cause of reduced efficiency. In the technical field of this disclosure, it is desired to improve the efficiency of plant design.

This disclosure describes a design support apparatus and a design support system with which the efficiency of plant design can be improved.

### Solution to Problem

(Item 1) A design support apparatus according to one aspect of this disclosure is an apparatus for supporting a plant design including a plurality of design steps. This design support apparatus includes: a storage unit configured to store a graph structure data in which a component included in a plant to be designed is defined as a node and a connection relationship between two components is defined as an edge; an acquisition unit configured to acquire the graph structure data from the storage unit in response to an acquisition request from a terminal apparatus configured to perform each of the plurality of design steps; an output unit configured to output the graph structure data to the terminal apparatus; and an update unit configured to update the graph structure data stored in the storage unit based on an output data of a design step performed on the terminal apparatus through use of the graph structure data. The graph structure data is shared among the plurality of design steps and becomes more detailed as the plant design progresses from an upstream step to a downstream step of the plant design.

In the above-mentioned design support apparatus, the graph structure data in which the component included in the plant to be designed is defined as the node and the connection relationship between two components is defined as the edge is stored in the storage unit. Further, in response to the acquisition request from the terminal apparatus, the graph structure data is acquired from the storage unit and output to the terminal apparatus. The graph structure data stored in the storage unit is updated based on the output data of the design step performed on the terminal apparatus through use of the graph structure data. The plant can be expressed by using the plurality of components for executing a series of processes from a raw material to obtaining an end product, and the connection relationships between two components. In plant design, process granularity becomes finer as the design progresses. As the process granularity becomes finer, the number of components increases, but through the plant design, the plant can be expressed by the plurality of components and the connection relationships between two components. Therefore, by defining the component to be included in the plant as the node and the connection relationship between two components as the edge, graph structure data can be shared among a plurality of design steps without preparing data individually for each design step. This enables the graph structure data to gradually become more detailed as the plant design progresses from an upstream step to a downstream step of the plant design. As a result, it becomes possible to improve the efficiency of the plant design.

(Item 2) In the design support apparatus according to Item 1, the update unit may be configured to add an attribute data of the node included in the graph structure data to the graph structure data stored in the storage unit.

In plant design, attributes such as the arrangement position of the node are determined in some design steps. With the above-mentioned update processing, output data of such a design step can be reflected in the graph structure data.

(Item 3) In the design support apparatus according to Item 1 or 2, the update unit may be configured to add an attribute data of the edge included in the graph structure data to the graph structure data stored in the storage unit.

In plant design, attributes such as a piping diameter of the edge are determined in some design steps. With the above-mentioned update processing, output data of such a design step can be reflected in the graph structure data.

(Item 4) In the design support apparatus according to any one of Items 1 to 3, the update unit may be configured to add an edge to the graph structure data stored in the storage unit.

In the plant, common fluids such as a heat medium, a refrigerant, and a fuel gas required for refining a raw material fluid are used, and piping along which the common fluids are to flow is used. Thus, piping may be added in some design steps. With the above-mentioned update processing, output data of such a design step can be reflected in the graph structure data.

(Item 5) In the design support apparatus according to any one of Items 1 to 4, the update unit may be configured to add a node to the graph structure data stored in the storage unit, and to add an edge connecting the added node to another node.

As described above, in plant design, process granularity becomes finer as the design progresses. As the process granularity becomes finer, components are added and piping connected to the added components is added. With the above-mentioned update processing, output data of such a design step can be reflected in the graph structure data.

(Item 6) A design support system according to another aspect of this disclosure includes: the design support apparatus of any one of Items 1 to 5; and a plurality of terminal apparatus. Each of the plurality of terminal apparatus is configured to perform one of the plurality of design steps.

This design support system includes the above-mentioned design support apparatus, and hence it is possible to improve the efficiency of plant design in the design support system as well.

(Item 7) In the design support system according to Item 6, the plurality of terminal apparatus may include a first terminal apparatus configured to perform a three-dimensional modeling of the plurality of design steps. The first terminal apparatus may be configured to use the graph structure data to display a three-dimensional model of the plant on a display apparatus.

In this case, the plant to be designed is displayed as a three-dimensional model. Therefore, the plant is visualized, and hence a user can easily recognize the arrangement of each component and each piece of piping in the plant.

### Advantageous Effects of Invention

According to each aspect and each embodiment of this disclosure, it is possible to improve the efficiency of the plant design.

### BRIEF DESCRIPTION OF DRAWINGS

FIG. 1 is a configuration diagram for schematically illustrating a design support system including a design support apparatus according to one embodiment of this disclosure.

FIG. 2 is a hardware configuration diagram of the design support apparatus illustrated in FIG. 1.

FIG. 3 is a block diagram for illustrating a functional configuration of the design support apparatus illustrated in FIG. 1.

FIG. 4 is a table for showing an example of graph structure data.

FIG. 5 is a flowchart for illustrating an example of a design support method performed by the design support apparatus illustrated in FIG. 1.

FIG. 6 is a sequence diagram for illustrating an example of design steps in plant design.

FIG. 7 is a table for showing an example of the graph structure data after a process simulation execution step is executed.

FIG. 8 is a graph of the graph structure data shown in FIG. 7.

FIG. 9 is a sequence diagram for illustrating an example of a process flow diagram.

FIG. 10 is a table for showing an example of the graph structure data after a process flow diagram preparation step is executed.

FIG. 11 is a graph of the graph structure data shown in FIG. 10.

FIG. 12 is a table for showing an example of the graph structure data after a plot plan design step is executed.

FIG. 13 is a table for showing an example of the graph structure data after a hydraulic calculation execution step is executed.

FIG. 14 is a table for showing an example of the graph structure data after a piping and instrumentation diagram preparation step is executed.

FIG. 15 is a graph of the graph structure data shown in FIG. 14.

FIG. 16 is a diagram for illustrating an example of a three-dimensional model.

FIG. 17 is a table for showing an example of the graph structure data after a three-dimensional modeling step is executed.

FIG. 18 is a graph of the graph structure data shown in FIG. 17.

FIG. 19 is a diagram for illustrating a configuration of a design support program recorded in a recording medium.

FIG. 20 is a table for showing another example of the graph structure data after the three-dimensional modeling step is executed.

FIG. 21 is a graph of the graph structure data shown in FIG. 20.

### DESCRIPTION OF EMBODIMENTS

A detailed description is now given of an embodiment of this disclosure with reference to the accompanying drawings. In the description of the drawings, the same components are denoted by the same reference symbols, and a redundant description thereof is omitted.

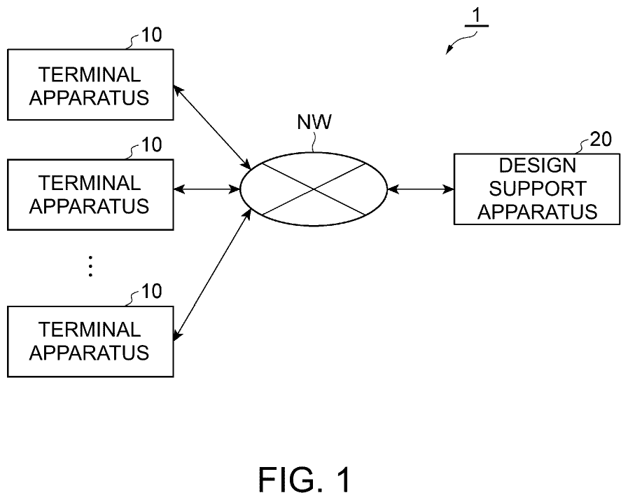

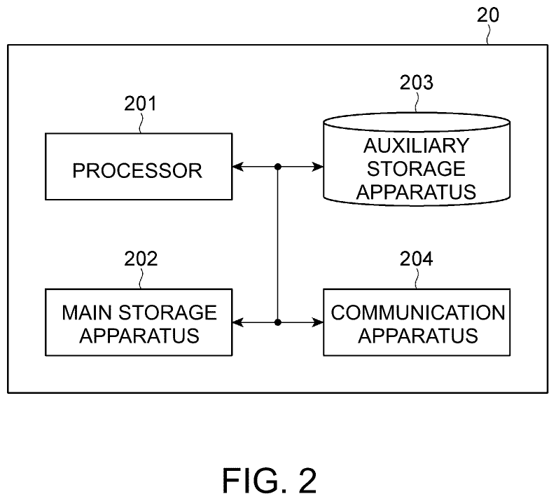

First, a design support system including a design support apparatus according to one embodiment of this disclosure is described with reference to FIG. 1 and FIG. 2. FIG. 1 is a configuration diagram for schematically illustrating the design support system including the design support apparatus according to the one embodiment. FIG. 2 is a hardware configuration diagram of the design support apparatus illustrated in FIG. 1.

A design support system 1 illustrated in FIG. 1 is a system for supporting plant design. An example of a plant to be designed is a plant in the oil/gas field. Examples of the plant in the oil/gas field include a petroleum refinery plant, a gas treatment plant, a natural gas liquefying plant, a petrochemical plant, and a chemical product manufacturing plant.

Plant design includes a plurality of design steps (design phases). Plant design includes design steps such as, for example, process simulation execution, preparation of a process flow diagram (PFD), plot plan design, hydraulic calculation execution, preparation of a piping and instrumentation diagram (P&ID), and 3D modeling. Details of each design step are described later.

The design support system 1 includes one or a plurality of terminal apparatus 10 and a design support apparatus 20. Each of the terminal apparatus 10 and the design support apparatus 20 are connected to each other for communication through a communication network NW. The communication network NW may be any one of a wired network and a wireless network. Examples of the communication network NW include the Internet, a mobile communication network, and a wide area network (WAN).

The terminal apparatus 10 is used by a user (designer) and executes various types of processing based on an operation by the user. Examples of the terminal apparatus 10 include a desktop computer, a laptop computer, a tablet terminal, and a smartphone. The user executes design steps by using, for example, a dedicated application for each design step on the terminal apparatus 10. The terminal apparatus 10 performs each of a plurality of design steps. One terminal apparatus 10 may execute only one design step, or may execute two or more design steps.

The terminal apparatus 10 transmits an acquisition request for acquiring graph structure data, which is described later, to the design support apparatus 20, and acquires the graph structure data from the design support apparatus 20. The terminal apparatus 10 executes a design step by using the graph structure data, and transmits output data of the design step to the design support apparatus 20.

The design support apparatus 20 is an apparatus for supporting plant design. The design support apparatus 20 holds graph structure data which is shared (commonly used) across all design steps. The design support apparatus 20 is constructed by an information processing apparatus such as a server apparatus.

As illustrated in FIG. 2, the design support apparatus 20 may be physically constructed as a computer including hardware components such as a processor 201, a main storage apparatus 202, an auxiliary storage apparatus 203, and a communication apparatus 204. The design support apparatus 20 may be constructed by one computer illustrated in FIG. 2, or may be constructed by a plurality of computers.

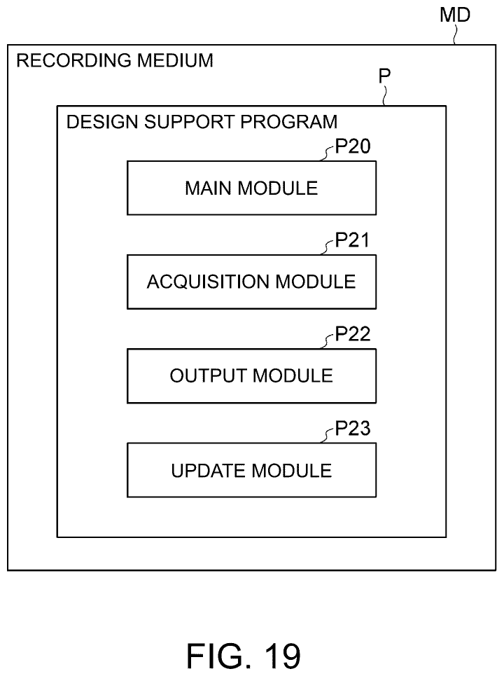

Examples of the processor 201 include a central processing unit (CPU). The main storage apparatus 202 is constructed by a random access memory (RAM), a read only memory (ROM), and the like. Examples of the auxiliary storage apparatus 203 include a semiconductor memory and a hard disk drive. The auxiliary storage apparatus 203 stores a design support program P (see FIG. 19). The communication apparatus 204 is an apparatus for transmitting and receiving data to and from other apparatus through the communication network NW. The communication apparatus 204 is constructed by, for example, a network interface card (NIC) or a wireless communication module.

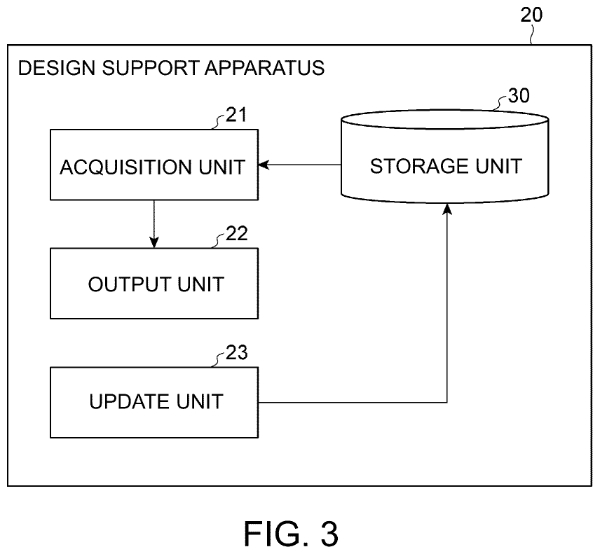

The processor 201 reads out the design support program P stored in the auxiliary storage apparatus 203 onto the main storage apparatus 202, and executes the design support program P so that the respective pieces of hardware operate under the control of the processor 201, and data is read out from and written to the main storage apparatus 202 and the auxiliary storage apparatus 203. As a result, respective function units of the design support apparatus 20 illustrated in FIG. 3 are implemented. Each terminal apparatus is also constructed by a computer similar to that of the design support apparatus 20.

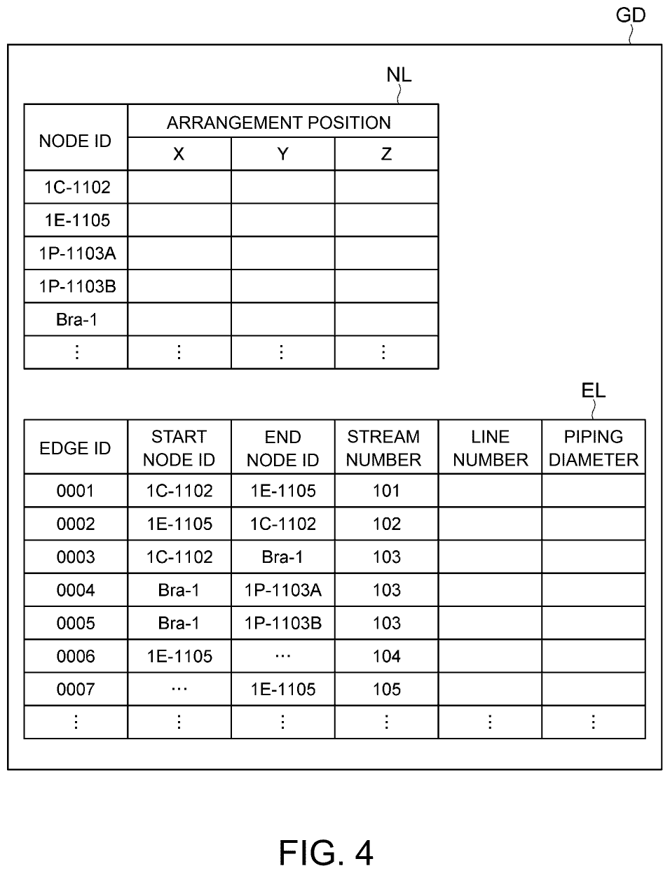

Next, a functional configuration of the design support apparatus 20 is described with reference to FIG. 3 and FIG. 4. FIG. 3 is a block diagram for illustrating a functional configuration of the design support apparatus illustrated in FIG. 1. FIG. 4 is a table for showing an example of graph structure data. As illustrated in FIG. 3, the design support apparatus 20 includes an acquisition unit 21, an output unit 22, an update unit 23, and a storage unit 30 as functional elements. A function (operation) of each function unit is described in detail when a design support method described later is described, and hence the function of each function unit is briefly described below.

The storage unit 30 is a functional element that stores graph structure data. In this embodiment, the graph structure data is data in which the components included in the plant are defined as nodes and the piping connecting two components is defined as edges. The components may include not only process devices but also piping branch parts and elbows, piping supports which support piping, and the like. The storage unit 30 stores graph structure data for each plant to be designed, for example. The graph structure data is shared among the plurality of design steps, and becomes more detailed as the plant design progresses from an upstream step to a downstream step of the plant design.

As shown in FIG. 4, graph structure data GD includes a plant identifier (ID) (not shown), a node list NL, and an edge list EL. The plant ID is information with which the plant to be designed is uniquely identified.

The node list NL is a list of the nodes included in the plant identified by the plant ID. The node list NL includes a record set for each node. Each record includes a node ID and arrangement position information. The node ID is information that enables a node to be uniquely identified. The arrangement position information is information indicating an arrangement position of the node identified by the node ID. In this embodiment, the arrangement position information includes an X coordinate, a Y coordinate, and a Z coordinate. The origin of an XYZ coordinate system is set in advance at a predetermined position.

The edge list EL is a list of the edges included in the plant identified by the plant ID. An edge represents a link (connection relationship) between two nodes. The edge list EL includes a record set for each edge. Each record includes an edge ID, a start node ID, an end node ID, a stream number, a line number, and attribute data.

The edge ID is information that enables an edge to be uniquely identified. The start node ID is the node ID of a start node. A fluid flows in one direction along the edge (piping) connecting two nodes. The start node is, of the two nodes connected by the edge identified by the edge ID, the node positioned upstream. The end node ID is the node ID of an end node. The end node is, of the two nodes connected by the edge identified by the edge ID, the node downstream.

The stream number is a number assigned to the fluid flowing along the edge identified by the edge ID. Identical fluids are assigned identical stream numbers. The range in which stream numbers are assigned is relatively large, and hence stream numbers are not suitable for detailed management.

The line number is a number obtained by subdividing the stream number, and is set in order to give separation in terms of design. The line number is set, for example, by subdividing the stream number from the viewpoint of drawing management and material management. A plurality of edges are grouped, and edges belonging to the same group are assigned the same line number. For example, a plurality of edges are divided into several groups based on attributes such as the type of fluid, design temperature, design pressure, and piping material, and the groups are divided based on piping branch parts.

The attribute data is information indicating the attributes of the edge identified by the edge ID. The attribute data includes a piping diameter (inner diameter) of the edge, as well as the composition, pressure, temperature, and required flow rate of the fluid flowing along the edge. The attribute data may include information indicating attributes other than the piping diameter.

The acquisition unit 21 is a functional element that acquires the graph structure data from the storage unit 30 in response to an acquisition request from the terminal apparatus 10. The acquisition unit 21 outputs the acquired graph structure data to the output unit 22.

The output unit 22 is a functional element that outputs the graph structure data to the terminal apparatus 10 that has transmitted the acquisition request.

The update unit 23 is a functional element that updates the graph structure data stored in the storage unit 30. The update unit 23 updates the graph structure data stored in the storage unit 30 based on the output data of a design step performed on the terminal apparatus 10 through use of the graph structure data.

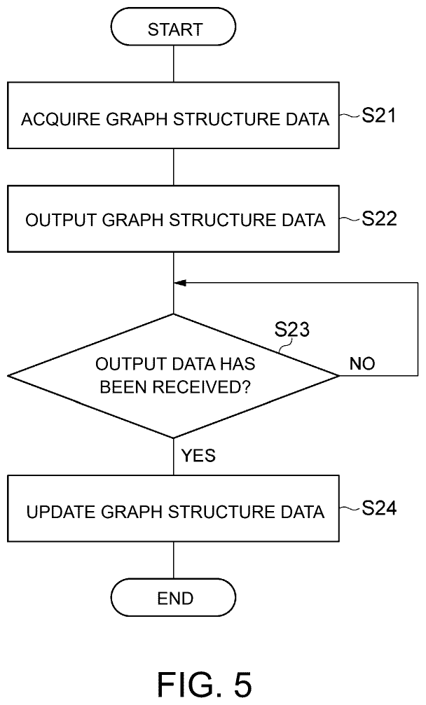

Next, the design support method performed by the design support apparatus 20 is described with reference to FIG. 5. FIG. 5 is a flowchart for illustrating an example of the design support method performed by the design support apparatus illustrated in FIG. 1. The flowchart of FIG. 5 is started when the acquisition unit 21 of the design support apparatus 20 receives an acquisition request from any terminal apparatus 10. The graph structure data is stored in the storage unit 30 in advance.

As illustrated in FIG. 5, first, the acquisition unit 21 acquires the graph structure data from the storage unit 30 (Step S21). The acquisition unit 21 then outputs the acquired graph structure data to the output unit 22. Subsequently, when the output unit 22 receives the graph structure data from the acquisition unit 21, the output unit 22 outputs (transmits) the graph structure data to the terminal apparatus 10 that has transmitted the acquisition request (Step S22).

Subsequently, the update unit 23 determines whether or not output data has been received from the terminal apparatus 10 (Step S23). The output data is output data of a design step performed on the terminal apparatus 10 through use of the graph structure data. When it is determined in Step S23 that the update unit 23 has not received output data (NO in Step S23), the determination of Step S23 is repeated until the update unit 23 receives output data. When it is determined in Step S23 that the update unit 23 has received output data (YES in Step S23), the update unit 23 updates the graph structure data stored in the storage unit 30 based on the received output data (Step S24).

As a result, the series of processing steps of the design support method is finished.

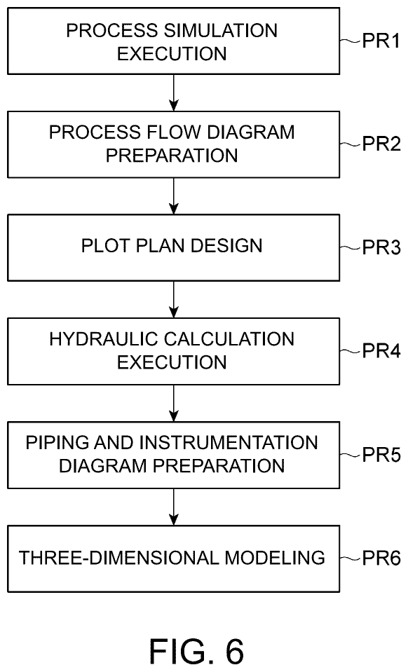

Next, a series of steps of a flow of plant design is described with reference to FIG. 6. FIG. 6 is a sequence diagram for illustrating an example of design steps in plant design.

As illustrated in FIG. 6, the plant design includes a process simulation execution step PR1, a process flow diagram preparation step PR2, a plot plan design step PR3, a hydraulic calculation execution step PR4, a piping and instrumentation diagram preparation step PR5, and a three-dimensional modeling step PR6. The following description is given based on the assumption that the process simulation execution step PR1, the process flow diagram preparation step PR2, the plot plan design step PR3, the hydraulic calculation execution step PR4, the piping and instrumentation diagram preparation step PR5, and the three-dimensional modeling step PR6 are executed in the stated order.

Each step may be executed by a different terminal apparatus 10. Two or more steps may be executed by the same terminal apparatus 10. Each step is executed through use of a dedicated application installed on the terminal apparatus 10, for example.

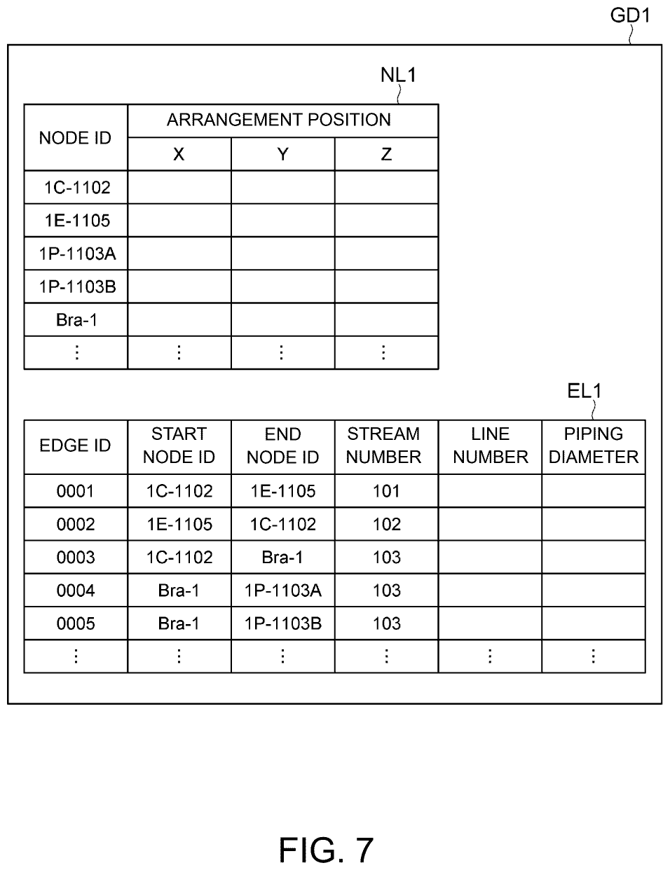

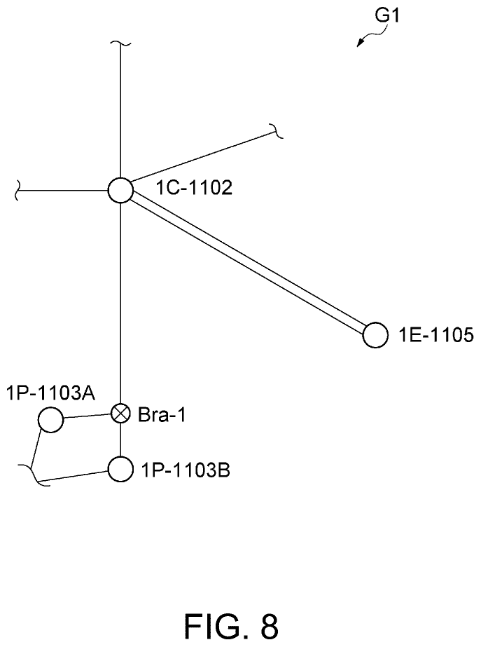

First, the process simulation execution step PR1 is executed. The process simulation execution step is described in detail with reference to FIG. 7 and FIG. 8. FIG. 7 is a table for showing an example of the graph structure data after the process simulation execution step is executed. FIG. 8 is a graph of the graph structure data shown in FIG. 7.

The process simulation execution step PR1 is a step of determining design specifications of main components (main devices) and design specifications of fluids flowing along main piping for producing an end product from a raw material. Examples of the raw material include crude oil and source gas. Examples of the end product include refined gas, oil, and chemical products. Examples of the main devices include distillation columns, heat exchangers, and pumps. The design specifications of the main devices include a throughput that determines the functions of the main devices. The design specifications of the fluids include composition, pressure, and temperature.

The user of the terminal apparatus 10 executing the process simulation execution step PR1 starts a process simulator on the terminal apparatus 10. The process simulator is a dedicated application for executing process simulations. The user creates a schematic of the production steps (arrangement order of main devices and main piping connecting the main devices) for producing the end product from the raw material on a screen of a display apparatus of the terminal apparatus 10 based on the design standards, specification documents, and information on the properties of the raw material. The user may read out data on past similar plant designs as template data, and create a schematic of the main devices and main piping based on the template data.

The user then uses the created schematic of the main devices and main piping to cause the process simulator to execute a process simulation, and determines the various design specifications based on simulation results obtained by the process simulator.

When the user performs, on the terminal apparatus 10, an operation to save the determined design specifications, the terminal apparatus 10 transmits, to the design support apparatus 20, the node ID of each main device used in the process simulation and a set including the edge ID, the start node ID, the end node ID, the stream number, and the design specifications of the fluid flowing along the main piping that have been set for each piece of main piping used in the process simulation as output data together with the plant ID of the plant to be designed.

When the update unit 23 of the design support apparatus 20 receives the output data from the terminal apparatus 10, the update unit 23 updates the graph structure data stored in the storage unit 30. The graph structure data for the relevant plant is not stored in the storage unit 30, and hence the update unit 23 generates new graph structure data GD1 based on the output data, and stores the generated graph structure data GD1 in the storage unit 30.

As shown in FIG. 7, the graph structure data GD1 includes the plant ID (not shown), a node list NL1, and an edge list EL1. The node list NL1 is a list of the main devices used in the process simulation. The update unit 23 generates the node list NL1 by generating, for each main device, a record including the node ID. Each record includes no valid value for the arrangement position information. The records may include the design specifications of the main device as attribute data. In FIG. 7, the node identified by the node ID “1C-1102″ is a distillation column. The node identified by the node ID ”1E-1105″ is a heat exchanger that serves as a heat source for the distillation column. The nodes identified by the node IDs “1P-1103A” and “1P-1103B” are pumps that pump heavy ingredients. The node identified by the node ID “Bra-1” is a piping branch part.

The edge list EL1 is a list of the pieces of main piping used in process simulation. The update unit 23 generates the edge list EL1 by generating, for each piece of main piping, a record including the edge ID, the start node ID, the end node ID, the stream number, and attribute data. Each record includes the design specifications of the fluid flowing along the main piping as attribute data (not shown in FIG. 7). Each record includes no valid value for the line number.

As shown in FIG. 8, the graph structure data GD1 can be expressed as a graph G1 by representing each node with a circle and each edge with a line. The graph G1 represents the topology of the plant to be designed.

When the graph structure data of the plant to be designed is stored in the storage unit 30 before the process simulation execution step PR1 is executed, the process simulation may be executed by using the graph structure data acquired from the design support apparatus 20.

Specifically, in the process simulator, when the user performs an operation to read out the graph structure data of the plant to be designed, the terminal apparatus 10 transmits an acquisition request including the plant ID of the plant to the design support apparatus 20. When the acquisition unit 21 of the design support apparatus 20 receives the acquisition request from the terminal apparatus 10, the acquisition unit 21 acquires, from the storage unit 30, the graph structure data including the plant ID included in the acquisition request, and outputs the acquired graph structure data to the output unit 22. Then, the output unit 22 transmits the graph structure data GD1 received from the acquisition unit 21 to the terminal apparatus 10 that has transmitted the acquisition request. When the terminal apparatus 10 receives the graph structure data from the design support apparatus 20, the terminal apparatus 10 executes a process simulation based on the graph structure data.

Each time a record of a new node is added to the node list of the graph structure data, component data of the node is generated and registered in a database (not shown). The component data is also referred to as “tag information.” The component data includes, for example, the node ID and attribute data. The attribute data is information indicating the attributes of the node identified by the node ID. The component data may include the design specifications of the main device as attribute data.

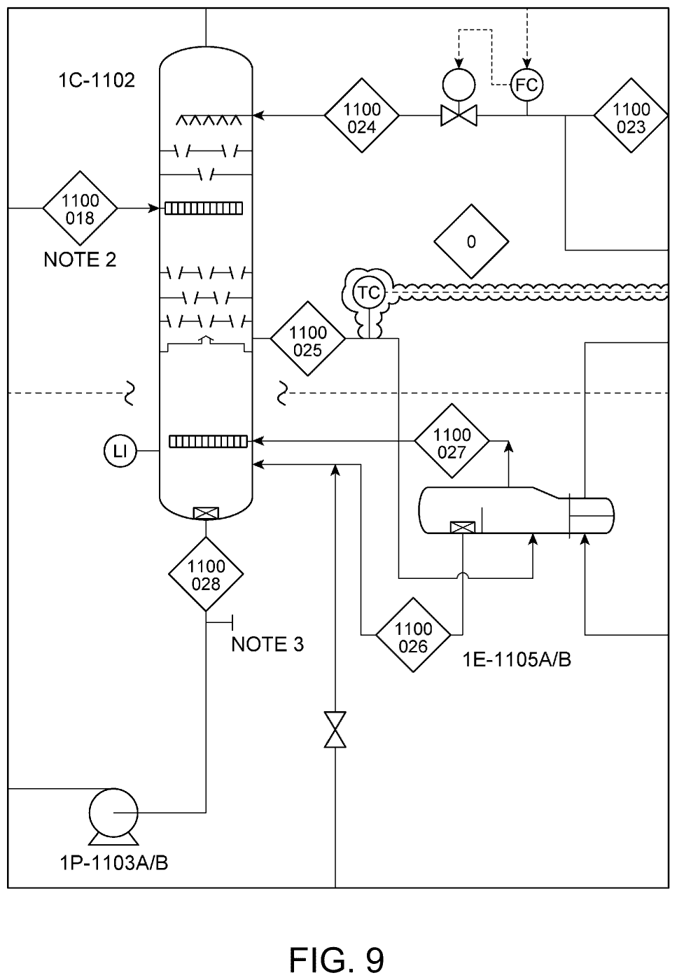

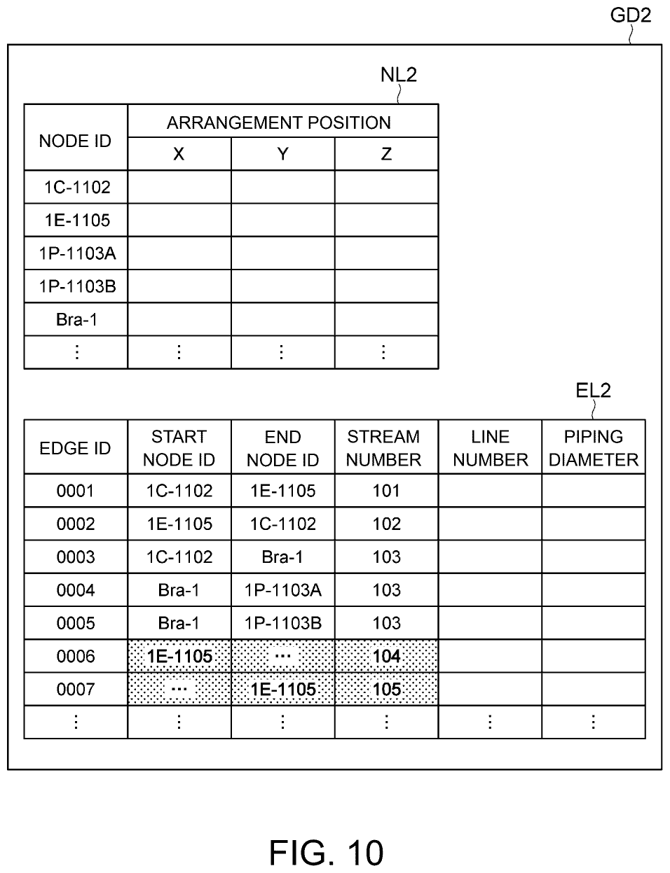

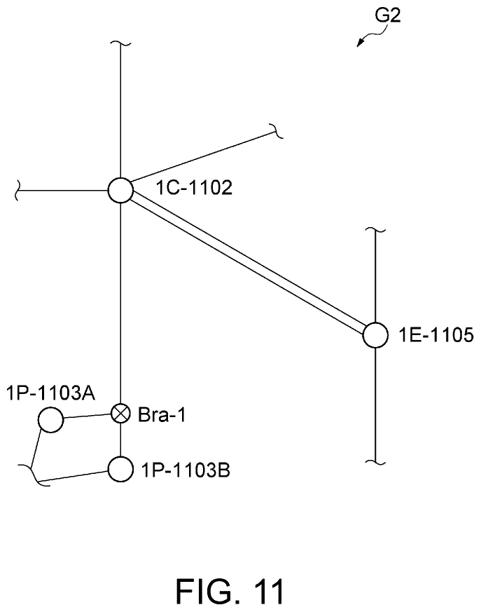

Subsequently, the process flow diagram preparation step PR2 is executed. The process flow diagram preparation step is described in detail with reference to FIG. 9 to FIG. 11. FIG. 9 is a sequence diagram for illustrating an example of a process flow diagram. FIG. 10 is a table for showing an example of the graph structure data after the process flow diagram preparation step is executed. FIG. 11 is a graph of the graph structure data shown in FIG. 10. The process flow diagram preparation step PR2 is a step of creating (preparing) a process flow diagram. In addition to the components and the piping used in the process simulation, components and piping that do not require a process simulation are added to the process flow diagram.

The user of the terminal apparatus 10 executing the process flow diagram preparation step PR2 starts a dedicated application for creating a process flow diagram on the terminal apparatus 10. When the user performs an operation to read out the graph structure data of the plant to be designed, the terminal apparatus 10 transmits an acquisition request including the plant ID of the plant to the design support apparatus 20.

When the acquisition unit 21 of the design support apparatus 20 receives the acquisition request from the terminal apparatus 10, the acquisition unit 21 acquires, from the storage unit 30, the graph structure data (here, graph structure data GD1) including the plant ID included in the acquisition request, and outputs the graph structure data GD1 to the output unit 22. Then, the output unit 22 transmits the graph structure data GD1 received from the acquisition unit 21 to the terminal apparatus 10 that has transmitted the acquisition request.

When the terminal apparatus 10 receives the graph structure data GD1 from the design support apparatus 20, the terminal apparatus 10 displays the topology (unfinished process flow diagram) of the plant on the display apparatus based on the graph structure data GD1. As illustrated in FIG. 9, the user creates the process flow diagram by adding, on the screen of the display apparatus, the main piping of the shared fluids, main measurement devices, and main control parts (movable parts). The shared fluids are the heating medium, the refrigerant, the fuel gas, and the like required for refining the raw material fluid. The measurement devices are devices for measuring a flow rate, pressure, and the like. The control parts are parts for adjusting the flow rate, pressure, and the like. Cables (including wireless connections) connecting the measurement devices and the control parts may be treated as edges.

When the user performs, on the terminal apparatus 10, an operation to save the process flow diagram, the terminal apparatus 10 transmits the node ID of each newly added node and a set including the edge ID, the start node ID, the end node ID, and the stream number that have been set for each newly added edge to the design support apparatus 20 as output data together with the plant ID of the plant to be designed.

When the update unit 23 of the design support apparatus 20 receives the output data from the terminal apparatus 10, the update unit 23 updates the graph structure data GD1 stored in the storage unit 30 to graph structure data GD2. As shown in FIG. 10, the graph structure data GD2 includes a plant ID (not shown), a node list NL2, and an edge list EL2. For example, the update unit 23 generates the node list NL2 by generating a new record including the node ID of each node included in the output data, and adding the generated records to the node list NL1. The update unit 23 generates the edge list EL2 by generating new records including a set including the edge ID, the start node ID, the end node ID, and the stream number included in the output data, and adding the generated records to the edge list EL1.

Here, for convenience of description, only the heat medium piping of the heat exchanger identified by the node ID “1E-1105” is added. As shown in FIG. 11, the graph structure data GD2 can be expressed as a graph G2.

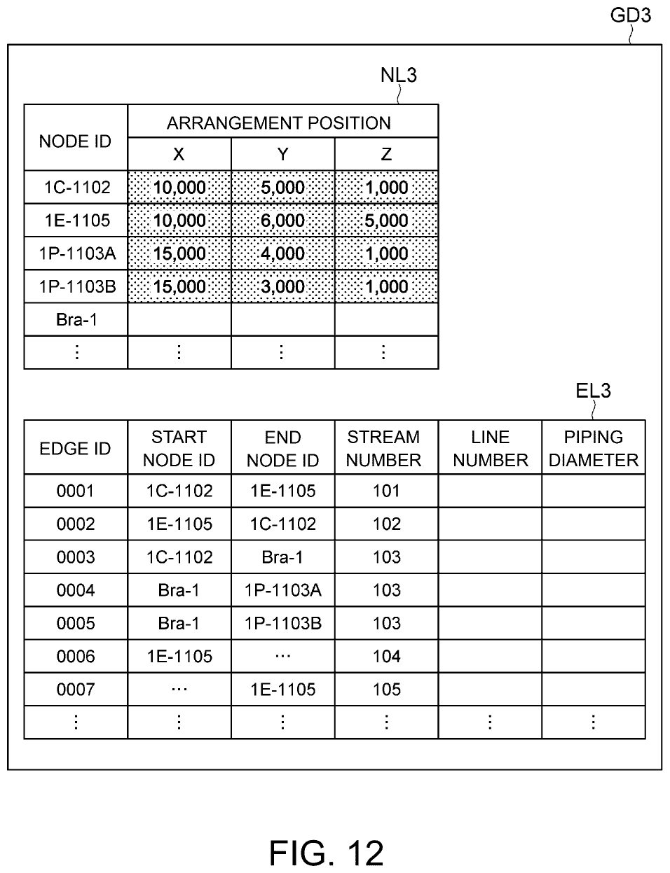

Next, the plot plan design step PR3 is executed. The plot plan design step is described in detail with reference to FIG. 12. FIG. 12 is a table for showing an example of the graph structure data after the plot plan design step is executed. The plot plan design step PR3 is a step of determining the arrangement positions of the devices. Therefore, new components and piping are not added in the plot plan design step PR3. The arrangement positions of components other than devices may also be determined.

The user of the terminal apparatus 10 executing the plot plan design step PR3 starts, on the terminal apparatus 10, a dedicated application for determining the arrangement positions of the devices. When the user performs an operation to read out the graph structure data of the plant to be designed, the terminal apparatus 10 transmits an acquisition request including the plant ID of the plant to the design support apparatus 20.

When the acquisition unit 21 of the design support apparatus 20 receives the acquisition request from the terminal apparatus 10, the acquisition unit 21 acquires, from the storage unit 30, the graph structure data (here, graph structure data GD2) including the plant ID included in the acquisition request, and outputs the graph structure data GD2 to the output unit 22. Then, the output unit 22 transmits the graph structure data GD2 received from the acquisition unit 21 to the terminal apparatus 10 that has transmitted the acquisition request.

When the terminal apparatus 10 receives the graph structure data GD2 from the design support apparatus 20, the terminal apparatus 10 determines the arrangement position of each device by taking into consideration various factors such as economic efficiency, maintainability, and operability based on information such as the size of each device and piping connections, and displays a schematic diagram showing the arrangement positions of the devices on the display apparatus. Regarding economic efficiency, consideration may be given to shortening the length of piping for the entire plant, for example. The terminal apparatus 10 acquires the information on the size of each device from a database (not shown). When the user performs, on the terminal apparatus 10, an operation to save the arrangement positions of the devices, the terminal apparatus 10 transmits a set including the node ID and arrangement position information of each device to the design support apparatus 20 as output data together with the plant ID of the plant to be designed.

When the update unit 23 of the design support apparatus 20 receives the output data from the terminal apparatus 10, the update unit 23 updates the graph structure data GD2 stored in the storage unit 30 to graph structure data GD3. As shown in FIG. 12, the graph structure data GD3 includes a plant ID (not shown), a node list NL3, and an edge list EL3. For example, the update unit 23 generates the node list NL3 by extracting the records including the node IDs included in the output data from the node list NL2, and adding the arrangement position information associated with the node IDs in the output data as the arrangement position information in the extracted records. The edge list EL2 is not changed, and hence the edge list EL3 is the same as the edge list EL2.

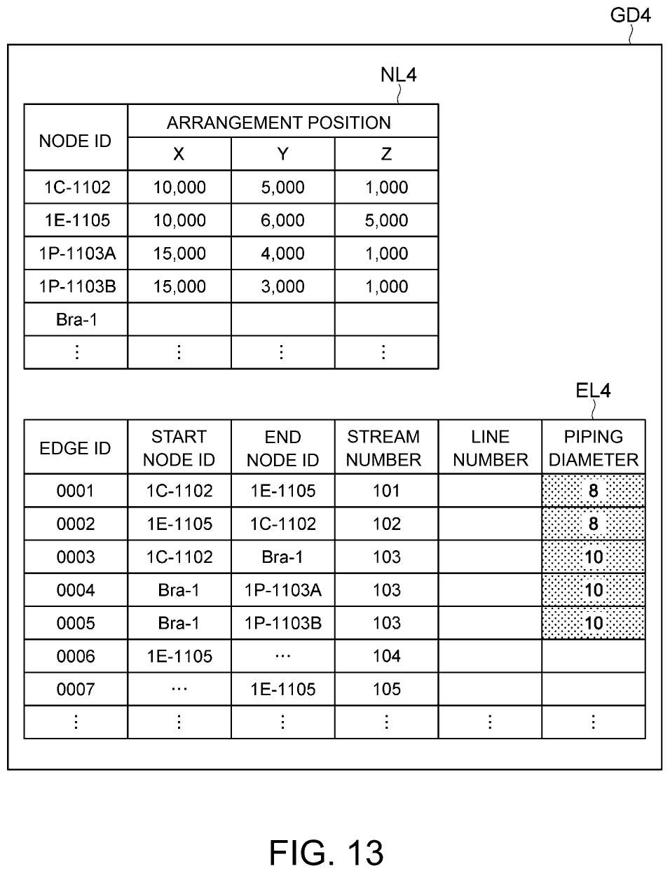

Subsequently, the hydraulic calculation execution step PR4 is executed. The hydraulic calculation execution step is described in detail with reference to FIG. 13. FIG. 13 is a table for showing an example of the graph structure data after the hydraulic calculation execution step is executed. The hydraulic calculation execution step PR4 is a step of determining the piping diameter (inner diameter) required in order to allow the required flow rate of each piece of piping to flow. The length of each piece of piping (piping length) is calculated in advance from the arrangement position of the device determined in the plot plan design step PR3. The piping length may be added as attribute data of each edge.

The user of the terminal apparatus 10 executing the hydraulic calculation execution step PR4 starts a dedicated application for executing the hydraulic calculation on the terminal apparatus 10. When the user performs an operation to read out the graph structure data of the plant to be designed, the terminal apparatus 10 transmits an acquisition request including the plant ID of the plant to the design support apparatus 20.

When the acquisition unit 21 of the design support apparatus 20 receives the acquisition request from the terminal apparatus 10, the acquisition unit 21 acquires, from the storage unit 30, the graph structure data (here, graph structure data GD3) including the plant ID included in the acquisition request, and outputs the graph structure data GD3 to the output unit 22. Then, the output unit 22 transmits the graph structure data GD3 received from the acquisition unit 21 to the terminal apparatus 10 that has transmitted the acquisition request.

When the terminal apparatus 10 receives the graph structure data GD3 from the design support apparatus 20, the terminal apparatus 10 calculates the piping diameter (inner diameter) that is required in order to allow the required flow rate to flow based on the piping length and the required flow rate of each piece of piping included in the graph structure data GD3 (edge list EL3). When the user performs, on the terminal apparatus 10, an operation to save the piping diameter of the piping, the terminal apparatus 10 transmits a set including the edge ID and the piping diameter of each piece of piping to the design support apparatus 20 as output data together with the plant ID of the plant to be designed.

When the update unit 23 of the design support apparatus 20 receives the output data from the terminal apparatus 10, the update unit 23 updates the graph structure data GD3 stored in the storage unit 30 to graph structure data GD4. As shown in FIG. 13, the graph structure data GD4 includes a plant ID (not shown), a node list NL4, and an edge list EL4. For example, the update unit 23 generates the edge list EL4 by extracting the records including the edge IDs included in the output data from the edge list EL3, and adding the piping diameter associated with the edge IDs in the output data as the piping diameter in the extracted records. The node list NL3 is not changed, and hence the node list NL4 is the same as the node list NL3.

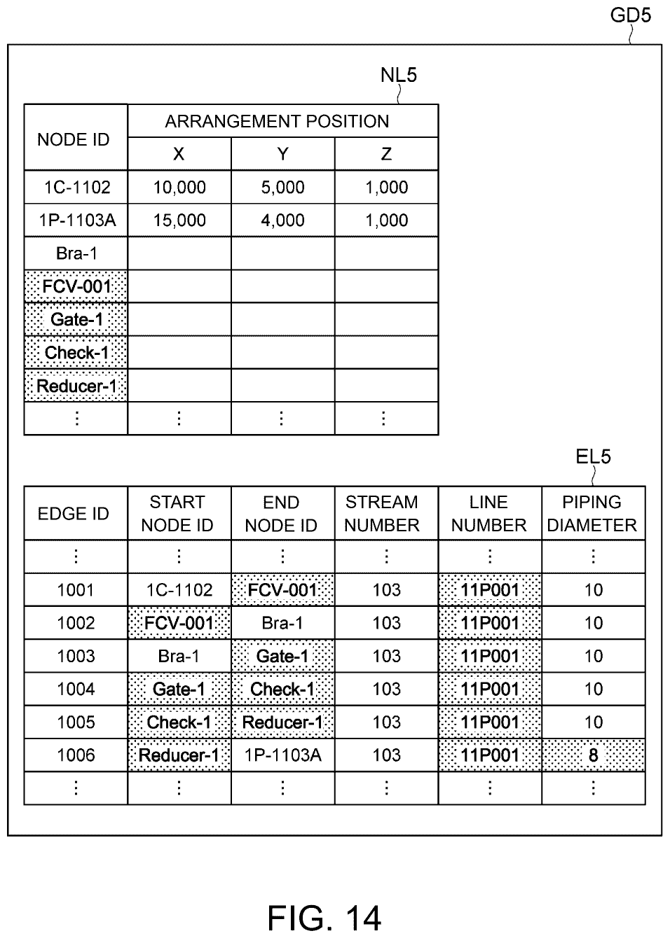

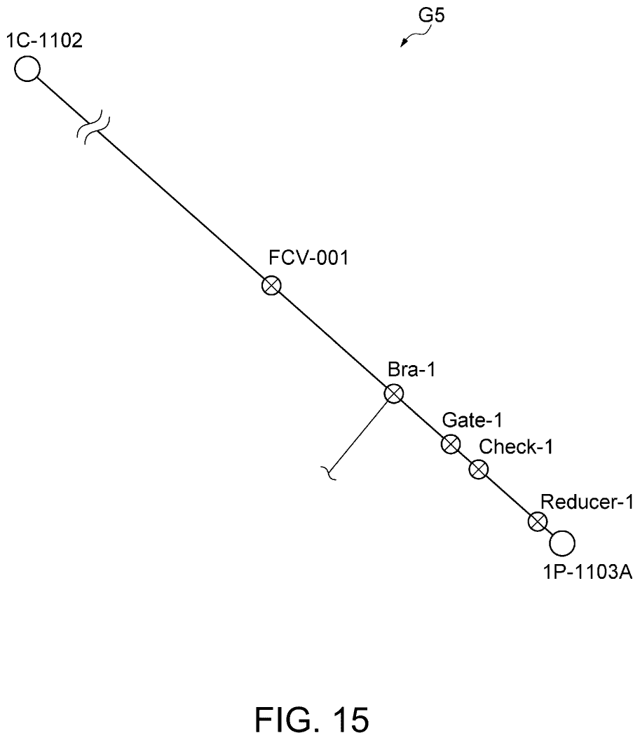

Subsequently, the piping and instrumentation diagram preparation step PR5 is executed. The piping and instrumentation diagram preparation step is described in detail with reference to FIG. 14 and FIG. 15. FIG. 14 is a table for showing an example of the graph structure data after the piping and instrumentation diagram preparation step is executed. FIG. 15 is a graph of the graph structure data shown in FIG. 14. The piping and instrumentation diagram preparation step PR5 is a step of creating (preparing) a piping and instrumentation diagram.

The user of the terminal apparatus 10 executing the piping and instrumentation diagram preparation step PR5 starts a dedicated application for creating a piping and instrumentation diagram on the terminal apparatus 10. When the user performs an operation to read out the graph structure data of the plant to be designed, the terminal apparatus 10 transmits an acquisition request including the plant ID of the plant to the design support apparatus 20.

When the acquisition unit 21 of the design support apparatus 20 receives the acquisition request from the terminal apparatus 10, the acquisition unit 21 acquires, from the storage unit 30, the graph structure data (here, graph structure data GD4) including the plant ID included in the acquisition request, and outputs the graph structure data GD4 to the output unit 22. Then, the output unit 22 transmits the graph structure data GD4 received from the acquisition unit 21 to the terminal apparatus 10 that has transmitted the acquisition request.

When the terminal apparatus 10 receives the graph structure data GD4 from the design support apparatus 20, the terminal apparatus 10 displays the topology (unfinished piping and instrumentation diagram) of the plant on the display apparatus based on the graph structure data GD4. The user creates the piping and instrumentation diagram by adding the various components (piping parts) on the screen of the display apparatus by taking into consideration maintenance, safety, control, and the like. Instead of a configuration in which the user manually adds the piping parts, the terminal apparatus 10 may automatically add the piping parts by using template data.

When the user performs, on the terminal apparatus 10, an operation to save the piping and instrumentation diagram, the terminal apparatus 10 transmits the node ID of each newly added node and a set including the edge ID, the start node ID, the end node ID, and the stream number that have been set for each newly added edge to the design support apparatus 20 as output data together with the plant ID of the plant to be designed.

When the update unit 23 of the design support apparatus 20 receives the output data from the terminal apparatus 10, the update unit 23 updates the graph structure data GD4 stored in the storage unit 30 to graph structure data GD5. As shown in FIG. 14, the graph structure data GD5 includes a plant ID (not shown), a node list NL5, and an edge list EL5. For example, the update unit 23 generates the node list NL5 by generating a new record including the node ID included in the output data, and adding the generated records to the node list NL4. Each record includes no valid value for the arrangement position information.

The update unit 23 generates the edge list EL5 by generating new records including a set including the edge ID, the start node ID, the end node ID, and the stream number included in the output data, and adding the generated records to the edge list EL4. The line number may be automatically assigned, for example, in accordance with a condition set in advance, or may be assigned by the user. As the condition set in advance, for example, an attribute such as the type of fluid, the design temperature, the design pressure, or the piping material is used.

When an edge is divided into two edges due to the addition of a new node on the edge, the two edges inherit the stream number and attribute data of the original edge. However, of the two edges divided by the addition of a reducer, the edge positioned downstream has a piping diameter different from the piping diameter of the original edge. Therefore, this edge inherits the stream number and the attribute data except the piping diameter of the original edge. The piping diameter of the edge positioned downstream may be determined based on the hydraulic calculation in the hydraulic calculation execution step PR4, or may be determined based on a nozzle size (nozzle diameter) of the device to which the edge is connected. After the piping diameter of the edge positioned downstream is determined, depending on the node to which the edge is connected (for example, a device such as a pump), the determined piping diameter may not be applicable. In that case, the piping diameter of the edge positioned upstream may be changed by executing the hydraulic calculation again.

In this example, the graph structure data of the portion from the distillation column identified by the node ID “1C-1102”, via the branch part identified by the node ID “Bra-1”, up to the pump identified by the node ID “1P-1103A” is shown. The node identified by the node ID “FCV-001″ is a flow control valve. The node identified by the node ID ”Gate-1″ is a gate valve. The node identified by the node ID “Check-1″ is a check valve. The node identified by the node ID ”Reducer-1″ is a part (reducer) that connects two pieces of piping having different piping diameters. As shown in FIG. 15, the above-mentioned portion of the graph structure data GD5 can be expressed as a graph G5.

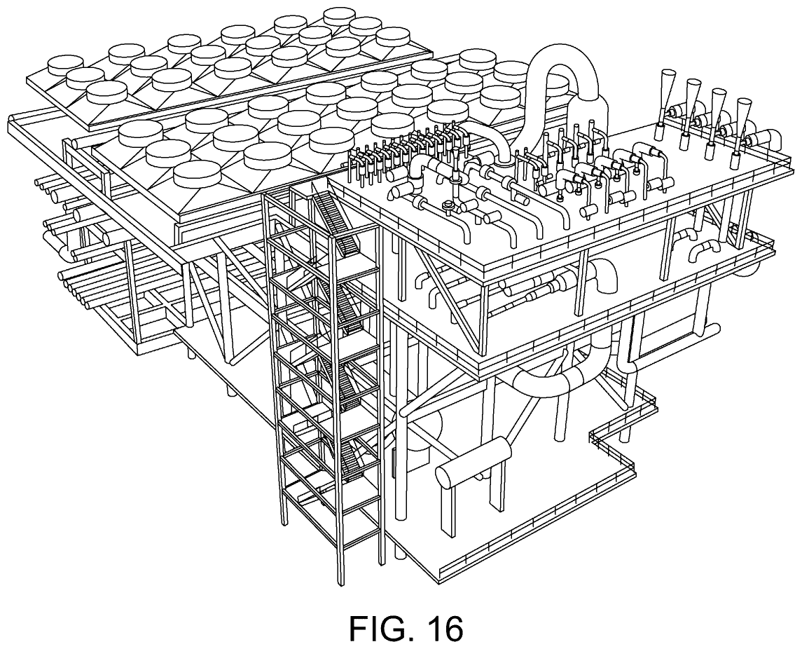

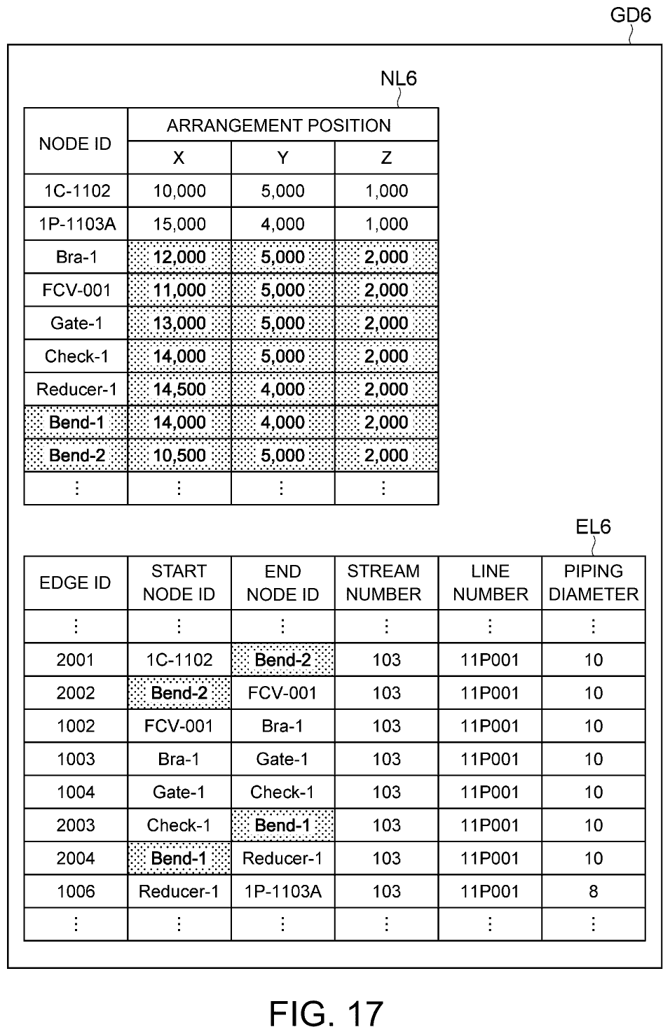

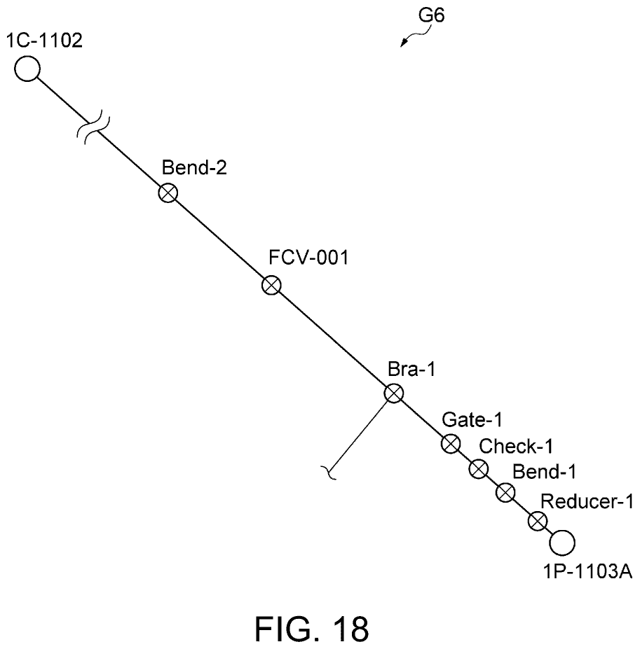

Subsequently, the three-dimensional modeling step PR6 is executed. The dimensional modeling step is described in detail with reference to FIG. 16 to FIG. 18. FIG. 16 is a diagram for illustrating an example of a three-dimensional model. FIG. 17 is a table for showing an example of the graph structure data after the three-dimensional modeling step is executed. FIG. 18 is a graph of the graph structure data shown in FIG. 17. The three-dimensional modeling step PR6 is a step of determining the arrangement position of each component in a three-dimensional space by using a three-dimensional model. In the three-dimensional modeling step PR6, parts that are not represented in the piping and instrumentation diagram, such as a part for bending piping (elbow) and a structural member for supporting the piping (piping support), may be added.

The user of the terminal apparatus 10 (first terminal apparatus) executing the three-dimensional modeling step PR6 starts a dedicated application for executing three-dimensional modeling on the terminal apparatus 10. When the user performs an operation to read out the graph structure data of the plant to be designed, the terminal apparatus 10 transmits an acquisition request including the plant ID of the plant to the design support apparatus 20.

When the acquisition unit 21 of the design support apparatus 20 receives the acquisition request from the terminal apparatus 10, the acquisition unit 21 acquires, from the storage unit 30, the graph structure data (here, graph structure data GD5) including the plant ID included in the acquisition request, and outputs the graph structure data GD5 to the output unit 22. Then, the output unit 22 transmits the graph structure data GD5 received from the acquisition unit 21 to the terminal apparatus 10 that has transmitted the acquisition request.

When the terminal apparatus 10 receives the graph structure data GD5 from the design support apparatus 20, the terminal apparatus 10 acquires three-dimensional model data of each node indicated by the node ID included in the node list NL5 from a database (not shown). Then, as illustrated in FIG. 16, the terminal apparatus 10 automatically routes the piping included in the edge list EL5, and generates a three-dimensional model of the plant. At this time, elbows and piping supports may be added. The user may manually generate the three-dimensional model on the screen.

When the user performs an operation to save the three-dimensional model on the terminal apparatus 10, the terminal apparatus 10 transmits a set including the node ID and arrangement position information of each node for which an arrangement position has been determined and a set including the edge ID, the start node ID, the end node ID, and the stream number that have been set for each edge arising from the newly added node to the design support apparatus 20 as output data together with the plant ID of the plant to be designed.

When the update unit 23 of the design support apparatus 20 receives the output data from the terminal apparatus 10, the update unit 23 updates the graph structure data GD5 stored in the storage unit 30 to graph structure data GD6. As shown in FIG. 17, the graph structure data GD6 includes a plant ID (not shown), a node list NL6, and an edge list EL6.

For example, the update unit 23 extracts the records including the node IDs included in the output data from the node list NL5, and adds the arrangement position information associated with the node IDs in the output data as the arrangement position information in the extracted records. When a record including the node ID included in the output data is not present in the node list NL5, the update unit 23 generates a record including the node ID and the arrangement position information associated with the node ID, and adds the generated record to the node list NL5. Through this series of procedures, the update unit 23 generates the node list NL6.

The update unit 23 generates the edge list EL6 by generating new records including a set including the edge ID, the start node ID, the end node ID, and the stream number included in the output data, and adding the generated records to the edge list EL5. When an edge is divided into two edges due to the addition of a new node on the edge, the two edges inherit the stream number, the line number, and attribute data of the original edge.

In this example, the graph structure data of the portion from the distillation column identified by the node ID “1C-1102”, via the branch part identified by the node ID “Bra-1”, up to the pump identified by the node ID “1P-1103A” is shown. The nodes identified by the node IDs “Bend-1″ and ”Bend-2″ are elbows. As shown in FIG. 18, the above-mentioned portion of the graph structure data GD6 can be expressed as a graph G6.

Next, referring to FIG. 19, description is given of the design support program P for causing a computer to function as the design support apparatus 20 and a recording medium MD for recording the design support program P. FIG. 19 is a diagram for illustrating a configuration of the design support program recorded in the recording medium.

As illustrated in FIG. 19, the design support program P includes a main module P20, an acquisition module P21, an output module P22, and an update module P23. The main module P20 is a part that integrally controls processing relating to the design support. Functions implemented by executing the acquisition module P21, the output module P22, and the update module P23 are the same as the functions of the acquisition unit 21, the output unit 22, and the update unit 23 in the embodiment described above, respectively.

The design support program P is provided by the recording medium MD. The recording medium MD is a computer-readable non-transitory recording medium. Examples of the recording medium MD include a compact disc-read only memory (CD-ROM), a digital versatile disc-read only memory (DVD-ROM), and a semiconductor memory. The design support program P may be provided as a data signal through the communication network NW.

In the design support system 1 and the design support apparatus 20 described above, the graph structure data in which each component included in the plant to be designed is defined as the node and the piping connecting two components is defined as the edge is stored in the storage unit 30. Further, in response to the acquisition request from the terminal apparatus 10, the graph structure data is acquired from the storage unit 30 and output to the terminal apparatus 10. The graph structure data stored in the storage unit 30 is updated based on the output data of a design step performed on the terminal apparatus 10 through use of the graph structure data.

The plant can be expressed by using the plurality of components for executing a series of processes from a raw material to obtaining an end product, and the piping (piping system) connecting two components. In plant design, process granularity becomes finer as the design progresses. As the process granularity becomes finer, the number of components increases, but through the plant design, the plant can be expressed by the plurality of components and the piping (piping system) connecting two components. Therefore, by defining the components to be included in the plant as nodes and the piping (piping system) connecting two components as edges, graph structure data can be shared among a plurality of design steps without preparing data individually for each design step. This enables the graph structure data to gradually become more detailed as the plant design progresses from an upstream step to a downstream step of the plant design. As a result, it becomes possible to improve the efficiency of the plant design.

The update unit 23 adds the attribute data of the nodes included in the graph structure data stored in the storage unit 30 to the graph structure data. In plant design, attributes such as the arrangement position of the node are determined in some design steps. With the above-mentioned update processing, output data of such a design step can be reflected in the graph structure data.

The update unit 23 adds the attribute data of the edges included in the graph structure data stored in the storage unit 30 to the graph structure data. In plant design, attributes such as the piping diameter of the edge are determined in some design steps. With the above-mentioned update processing, output data of such a design step can be reflected in the graph structure data.

The update unit 23 adds an edge to the graph structure data stored in the storage unit 30. In the plant, common fluids such as a heat medium, a refrigerant, and a fuel gas required for refining the raw material fluid are used, and piping along which the common fluids are to flow is used. Thus, piping may be added in some design steps. With the above-mentioned update processing, output data of such a design step can be reflected in the graph structure data.

The update unit 23 adds a node to the graph structure data stored in the storage unit 30, and adds an edge connecting the added node to another node. As described above, in plant design, process granularity becomes finer as the design progresses. As the process granularity becomes finer, components are added and piping connected to the added components is added. With the above-mentioned update processing, output data of such a design step can be reflected in the graph structure data.

The terminal apparatus 10 performing the three-dimensional modeling uses the graph structure data to display a three-dimensional model of the plant to be designed on the display apparatus. Therefore, the plant is visualized, and hence the user can easily recognize the arrangement of each component and each piece of piping in the plant.

The design support apparatus and the design support system according to this disclosure are not limited to those of the above-mentioned embodiment.

For example, the design support apparatus 20 may be constructed by one apparatus joined physically or logically, or may be constructed by a plurality of apparatus physically or logically separated from one another. For example, the design support apparatus 20 may be implemented by a plurality of computers distributed on the communication network NW as in the cloud computing.

When a physical piping member is added in the three-dimensional modeling step PR6, the piping diameter of the edges in the edge lists EL1 to EL5 may represent the inner diameter of the piping system rather than the inner diameter of the physical piping member. As used herein, the piping diameter is not limited to the inner diameter, and may be the outer diameter or the nominal diameter. Further, when the piping system includes parts having a plurality of diameters, the piping diameter may be a representative diameter.

Each piece of piping (piping member) is a component (plant device) arranged in the plant, and hence may be treated as a node. Similarly, cables (including wireless connections) connecting the measurement devices and the control parts may be treated as nodes. In this case, the connection relationship between two components is treated as an edge. That is, the graph structure data may be data in which all the components included in the plant, including the piping, are defined as nodes, and the connection relationships between two components are defined as edges.

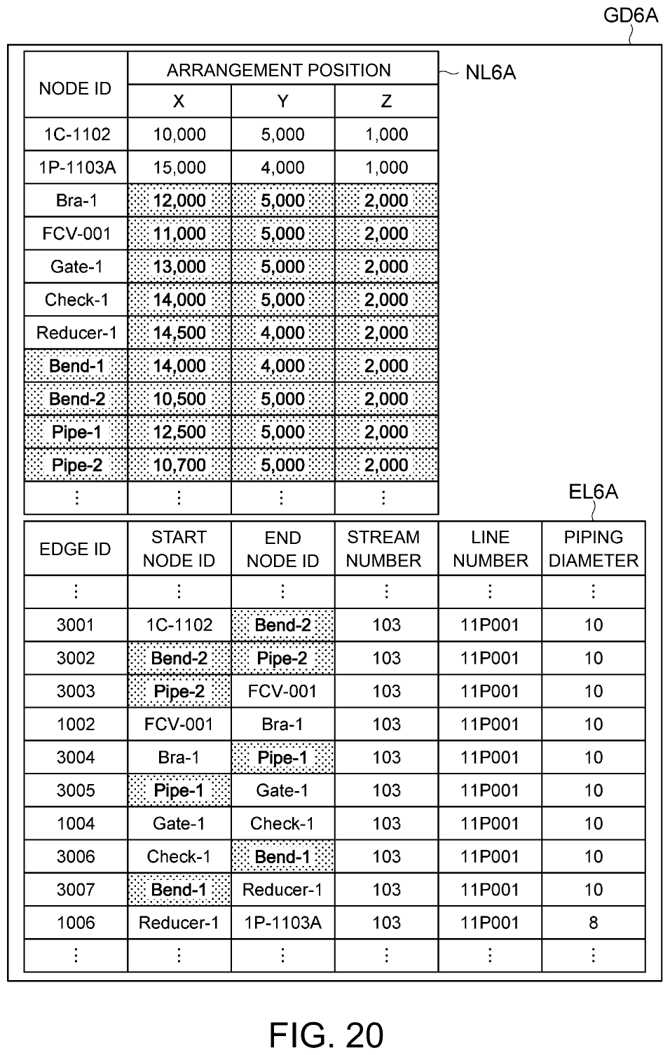

In the three-dimensional modeling step PR6, piping members are added. Therefore, as shown in FIG. 20, in a node list NL6A of graph structure data GD6A, records including the node ID of each added piping member and the arrangement position information associated with the relevant node ID are further added to the node list NL6 of the graph structure data GD6. In an edge list EL6A of the graph structure data GD6A, records including the node ID of each added piping member as the start node ID or the end node ID are further added to the edge list EL6 of the graph structure data GD6.

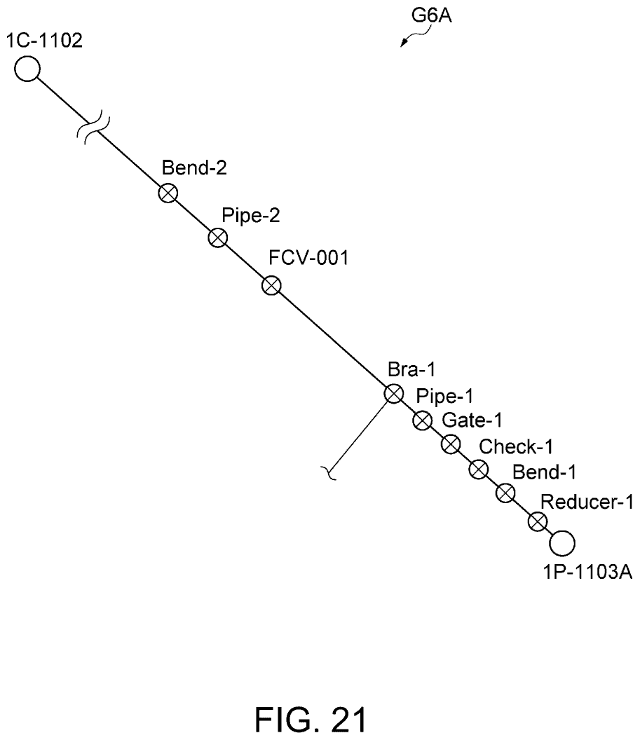

The nodes identified by the node IDs “Pipe-1″ and ”Pipe-2″ are pieces of piping (piping members). It is not required that piping be present between two non-piping components. The presence or absence of piping is determined in accordance with the layout. For example, two valves may be connected directly, or two valves may be connected via piping. As shown in FIG. 21, the above-mentioned portion of the graph structure data GD6A can be expressed as a graph G6A.

The plant can also be expressed by the plurality of components including the piping, for executing a series of processes from a raw material to obtaining an end product, and the connection relationships between two components. As described above, in plant design, the number of components increases as the design progresses, but through the plant design, the plant can be expressed by the plurality of components and the connection relationships between two components. Therefore, by defining the components to be included in the plant as nodes and the connection relationships between two components as edges, graph structure data can be shared among a plurality of design steps without preparing data individually for each design step. This enables the graph structure data to gradually become more detailed as the plant design progresses from an upstream step to a downstream step of the plant design. As a result, it becomes possible to improve the efficiency of the plant design.

### Reference Signs List

1 design support system, 10 terminal apparatus (first terminal apparatus), 20 design support apparatus, 21 acquisition unit, 22 output unit, 23 update unit, 30 storage unit

1. A design support apparatus for supporting a plant design including a plurality of design steps, the design support apparatus comprising:
a storage unit, configured to store a graph structure data in which a component included in a plant to be designed is defined as a node and a connection relationship between two components is defined as an edge;
an acquisition unit, configured to acquire the graph structure data from the storage unit in response to an acquisition request from a terminal apparatus configured to perform each of the plurality of design steps;
an output unit, configured to output the graph structure data to the terminal apparatus; and
an update unit, configured to update the graph structure data stored in the storage unit based on an output data of a design step performed on the terminal apparatus through use of the graph structure data,
wherein the graph structure data is shared among the plurality of design steps and becomes more detailed as the plant design progresses from an upstream step to a downstream step of the plant design.

2. The design support apparatus according to claim 1, wherein
the update unit is configured to add an attribute data of the node included in the graph structure data to the graph structure data stored in the storage unit.

3. The design support apparatus according to claim 1, wherein
the update unit is configured to add an attribute data of the edge included in the graph structure data to the graph structure data stored in the storage unit.

4. The design support apparatus according to claim 1, wherein
the update unit is configured to add an edge to the graph structure data stored in the storage unit.

5. The design support apparatus according to claim 1, wherein
the update unit is configured to add a node to the graph structure data stored in the storage unit, and to add an edge connecting the added node to another node.

6. A design support system, comprising:
the design support apparatus of claim 1; and
a plurality of terminal apparatus,
wherein each of the plurality of terminal apparatus is configured to perform one of the plurality of design steps.

7. The design support system according to claim 6, wherein
the plurality of terminal apparatus include a first terminal apparatus configured to perform a three-dimensional modeling of the plurality of design steps, and
wherein the first terminal apparatus is configured to use the graph structure data to display a three-dimensional model of the plant on a display apparatus.
